(19) United States
(12) Patent Application Publication
(10) Pub. No.: US 2022/0018028 A1
(43) Pub. Date: Jan. 20, 2022

(54) METHOD FOR COATING A PIPE AND PIPE

(71) Applicant: TI Automotive (Heidelberg) GmbH, Heidelberg (DE)

(72) Inventors: Alexander TSCHACHTSCHAL, Heidelberg (DE); Christian SINN, Ladenburg (DE)

(21) Appl. No.: 17/374,496

(22) Filed: Jul. 13, 2021

(30) Foreign Application Priority Data
Jul. 15, 2020 (EP) 20185920.4

(51) Int. Cl. C23C 28/00; H05H 1/24; C23C 2/04

(52) U.S. Cl. CPC C23C 28/32; C23C 2/04; H05H 1/24

(57) ABSTRACT

A method for coating a pipe, in particular a motor vehicle pipe, wherein a metallic inner tube is used, and wherein the outer surface of the metallic inner tube is provided with at least one metal layer. A bonding layer is thereupon applied to the metal layer. The pipe is then provided with at least one outer layer. The bonding layer is applied via plasma coating.

### RELATED APPLICATIONS

The present disclosure claims priority to European Application 20185920.4 filed on Jul. 15, 2020, the entire contents of each of which are incorporated herein by reference.

### FIELD

The disclosure relates to a method for coating a pipe, in particular a motor vehicle pipe, preferably for fuels and/or hydraulic fluids, wherein a metallic inner tube is used, wherein the outer surface of the metallic inner tube is provided with at least one metal layer, wherein at least one bonding layer is thereupon applied to the metal layer, and wherein the pipe is thereupon provided with at least one outer layer. The disclosure further relates to a corresponding pipe, preferably for fuels and/or hydraulic fluids.

### BACKGROUND

Methods of the kind described above are known in practice in various embodiments. As a rule, the bonding layer is here applied within the framework of wet chemical methods. The bonding layer is here used dissolved in a solvent. In this respect, the known measures are open to criticism with respect to environmental aspects and health aspects. The known methods necessitate complicated pretreatment measures and cleaning measures for the surfaces to be coated. Within the framework of the wet chemical methods for bonding agent application, relatively complex parameter settings must be observed, specifically in particular with respect to the temperature, pH value and mixing ratio of the components. As a whole, the known measures are relatively complicated, and thus also expensive. Improvement is needed in this regard.

### BRIEF SUMMARY

The technical problem underlying the disclosure is to indicate a method of the kind described at the outset, in which the disadvantages mentioned above can be effectively avoided. In addition, the technical problem underlying the disclosure is to indicate a corresponding pipe. In order to resolve the technical problem, the disclosure instructs a method for coating a pipe, in particular a motor vehicle pipe, preferably for fuels and/or hydraulic fluids, wherein a metallic inner tube is used, wherein the outer surface of the metallic inner tube is provided with at least one metal layer, wherein at least one bonding layer is thereupon applied to the metal layer, and wherein the pipe is thereupon provided with at least one outer layer, and wherein at least the bonding layer is applied via plasma coating.

On the one hand, the disclosure is based on the discovery that applying the bonding layer via plasma coating can be done relatively easily and with little effort. The complicated parameter settings known from prior art or practice are eliminated. The method according to the disclosure is also characterized by advantages over the previously known methods when it comes to environmental aspects and health aspects. The bonding layers can be applied very homogeneously, and defects are quasi precluded in the process. The bonding layer can be reproducibly applied with a constant, low layer thickness. The method according to the disclosure or the coating according to the disclosure is further also characterized by relatively low costs.

According to the disclosure, at least one metal layer is applied to the outer surface of the metallic inner tube. In one especially recommended embodiment of the disclosure, the metal layer contains at least one metal from the group “aluminum, zinc, aluminum alloy, zinc alloy”. In particular so-called Galfan is here used as the zinc alloy, wherein this case involves a zinc-aluminum alloy that consists for the most part or in excess of 90% of zinc, as well as of aluminum and small amounts of rare earth metal and/or precious metal. The alloy contains about 3 to 7% w/w, preferably 4 to 6% w/w, and in particular 5% w/w of aluminum. The alloy preferably contains more than 92% w/w of zinc.

In a recommended embodiment of the method according to the disclosure, the metal layer is applied to the metallic inner tube via hot-dip coating. The metallic inner tube can here be guided through the molten metal for the metal layer, so that the metallic inner tube is wetted with the metal from outside. The metal layer is preferably applied to the inner tube with a layer thickness of 50 to 200 μm.

According to the disclosure, the bonding layer is applied to the metallic inner tube coated with the metal layer via plasma coating. This application of the bonding layer best takes place with a layer thickness of 10 nm to 10 μm, preferably of 10 nm to 1 μm, and in particular of 10 to 700 nm. It has proven beneficial to perform the plasma coating with the bonding agent at a normal pressure or at atmospheric pressure. It lies within the framework of the disclosure that plasma coating be performed as a physical vapor deposition and/or chemical vapor deposition process.

A plasma coating device is best used for plasma coating, and the material for the bonding layer is fed to the plasma coating device in powder form. It lies within the framework of the disclosure that the material for the bonding layer in the plasma coating device be converted into the gas phase and then be deposited onto the pipe in solid form.

According to the disclosure, an outer layer is applied to the bonding layer or over the bonding layer. In a preferred embodiment of the disclosure, this outer layer consists of at least one polymer or essentially of at least one polymer. The polymer preferably involves at least one polyamide and/or at least one polyolefin. In one embodiment, the outer layer consists of a polyamide or essentially of a polyamide, and in another embodiment of the disclosure, the outer layer consists of a polyolefin or essentially of a polyolefin.

One embodiment of the disclosure is characterized in that a chrome-free intermediate layer is interspersed between the metal layer and the bonding layer. It has been discovered that it is beneficial that the chrome-free intermediate layer have at least one phosphatizing agent, and in another embodiment consist or essentially consist of at least one phosphatizing agent. In one embodiment of the disclosure, the chrome-free intermediate layer is designed as a sealing layer, and this layer preferably has at least one polymer. The polymer involves in particular a polyvinyl polymer. One preferred embodiment is characterized in that the chrome-free intermediate layer or the sealing layer is applied with a thickness of 0.2 to 1 μm.

It lies within the framework of the disclosure that the outer layer, which preferably consists of at least one polymer, be applied to the chrome-free intermediate layer. In a highly recommended embodiment of the disclosure, the outer layer is applied with a layer thickness of 0.2 to 3 mm, and in particular of 1 to 3 mm.

In order to resolve the technical problem, the disclosure further teaches a pipe, in particular a motor vehicle pipe, preferably for fuels and/or hydraulic fluids, wherein the pipe has a metallic inner tube, wherein a metal layer is provided on the metallic inner tube, and wherein a bonding layer is present on the metal layer, and wherein the pipe additionally has an outer layer, and wherein the bonding layer is applied as a plasma coating.

In one embodiment, the metallic inner tube involves a multiwalled tube, in particular a double-walled tube. It here lies within the framework of the disclosure that a metal tape, in particular a steel tape, be rolled up into the tube for generating the multiwalled or double-walled tube.

The disclosure is based upon the discovery that applying the bonding layer between the metal layer and the outer layer brings with it very special advantages. On the one hand, this plasma coating can be performed very easily and with little effort. The complicated measures in the wet chemical method known from practice can be completely eliminated in the disclosure. In this regard, the environmental and health problems associated with the known measures can also be avoided. Complex parameter settings are completely eliminated in the disclosure. The bonding layer applied with the plasma coating can be applied in a reproducibly homogeneous manner and with a constant layer thickness. These measures are relatively cost effective, and can nonetheless be effectively and precisely implemented.

### BRIEF DESCRIPTION OF THE DRAWINGS

The disclosure will be described in greater detail below based on a drawing, which only shows an exemplary embodiment. Shown schematically on:

FIG. 1 is a perspective view of a pipe coated based on the method according to the disclosure,

FIG. 2 is a magnified cutout A from FIG. 1, and

FIG. 3 is a schematic view of a preferred embodiment of a plasma coating device suitable for the method according to the disclosure.

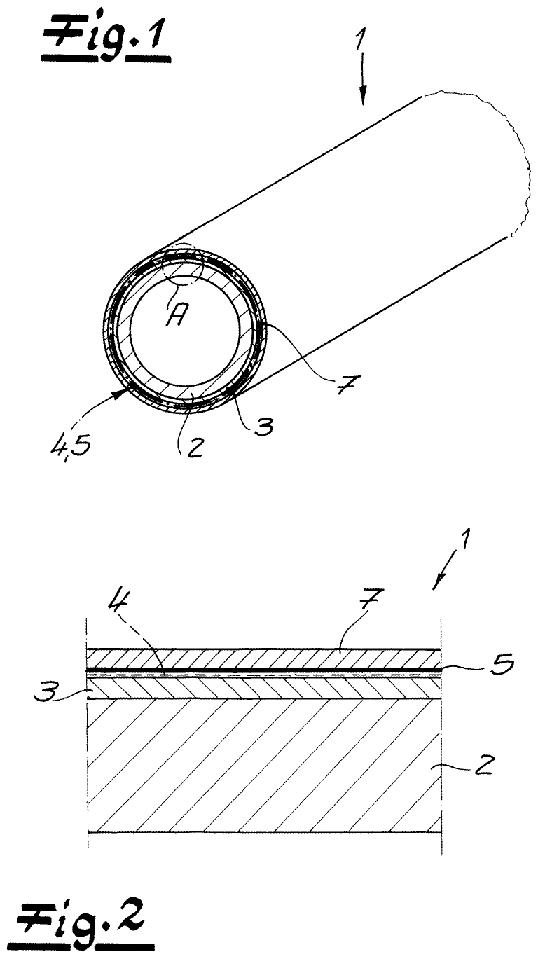

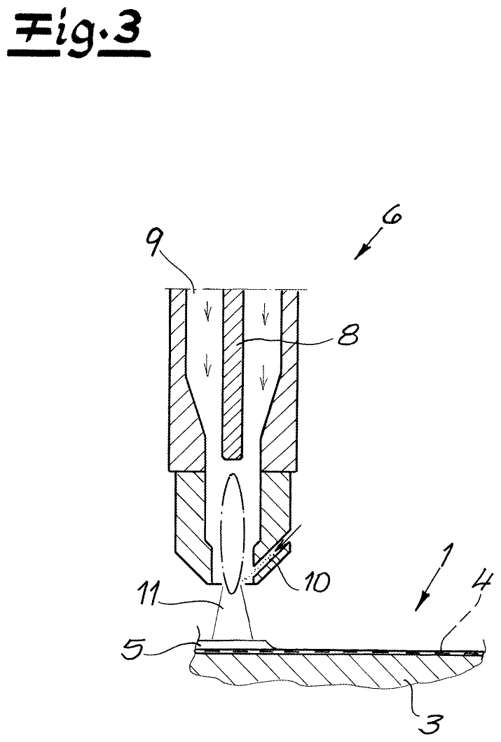

### DETAILED DESCRIPTION

The figures show a pipe 1, which was coated based on the method according to the disclosure. In the exemplary embodiment, a motor vehicle pipe can preferably be involved, which is preferably used for fuels and/or hydraulic fluids. The pipe 1 has a metallic inner tube 2, which in the exemplary embodiment is preferably designed as a steel tube. This metallic inner tube 2 is provided with a metal layer 3, which in the exemplary embodiment is preferably designed as an aluminum layer. The aluminum layer can have been applied to the metallic inner tube 2 in a hot-dip method. In particular, a metal layer 3 made of Galfan can be applied to the metallic inner tube 2 instead of an aluminum layer.

In a preferred embodiment and in the exemplary embodiment, a chrome-free intermediate layer 4 is applied to the metal layer 3 or the aluminum layer, and in one embodiment can have a phosphatizing agent.—The layer thickness of the metal layer 3 can measure 50 to 150 μm in the exemplary embodiment, and the layer thickness of the chrome-free intermediate layer 4 can measure 0.2 to 1 μm in the exemplary embodiment.

A bonding layer 5 is applied to the chrome-free intermediate layer 4. According to the disclosure, this bonding layer 5 is applied via plasma coating, and specifically preferably with a plasma coating device 6 shown on FIG. 3. The thickness of the bonding layer 5 can best measure 2 to 8 μm in the exemplary embodiment.—After the bonding layer 5 has been applied to the pipe 1, an outer layer 7 is preferably applied, which preferably and in the exemplary embodiment consists of polyamide or essentially of polyamide. The layer thickness of the outer layer 7 can measure 1 to 2 mm in the exemplary embodiment.

FIG. 3 shows a preferred embodiment of a plasma coating device 6, with which the bonding layer 5 is preferably applied to the pipe 1 via plasma coating. The electrode 8 of the plasma coating device 6 as well as the gas supply 9 are visible. The plasma coating device 6 has a channel 10, through which the material for the bonding layer 5 can be introduced in powder form. The material is then converted into the gas phase with the device 6, and finally applied to the pipe 1 as a bonding layer 5 in solid form. Also visible on FIG. 3 is the plasma jet 11 of the plasma coating device 6.

1. A method for coating a motor vehicle pipe, wherein a metallic inner tube is provided, wherein the outer surface of the metallic inner tube is provided with at least one metal layer, wherein at least one bonding layer is thereupon applied to the metal layer, wherein the pipe is thereupon provided with at least one outer layer, and wherein the at least the bonding layer is applied via plasma coating.

2. The method according to claim 1, wherein the metal layer contains at least one metal from the group “aluminum, zinc, aluminum alloy, zinc alloy”.

3. The method according to claim 1, wherein the metal layer is applied to the inner tube via hot-dip coating.

4. The method according to claim 1, wherein the metal layer is applied to the inner tube with a layer thickness of 50 to 200 μm.

5. The method according to claim 1, wherein the bonding layer is applied with a layer thickness of 10 nm to 10 μm.

6. The method according to claim 1, wherein the plasma coating is performed with the bonding agent at a normal pressure or at atmospheric pressure.

7. The method according to claim 1, wherein the plasma coating is performed as a physical vapor deposition and/or chemical vapor deposition process.

8. The method according to claim 1, wherein a plasma coating device is used for plasma coating, and that the material for the bonding layer is fed to the plasma coating device in powder form.

9. The method according to claim 1, wherein the material for the bonding layer is converted into the gas phase in the plasma coating device, and then deposited onto the pipe in solid form.

10. The method according to claim 1, wherein a layer of at least one polymer is used as the outer layer.

11. The method according to claim 1, wherein a chrome-free intermediate layer is interspersed between the metal layer and the bonding layer.

12. The method according to claim 11, wherein the chrome-free intermediate layer has at least one phosphatizing agent.

13. The method according to claim 1, wherein the chrome-free intermediate layer is applied with a thickness of 0.2 to 1 μm.

14. The method according to claim 1, wherein the outer layer is applied with a layer thickness of 0.2 to 3 mm.

15. A motor vehicle pipe configured for fuels and/or hydraulic fluids, coated according to claim 1, wherein the pipe has a metallic inner tube, wherein a metal layer is provided on the metallic inner tube, and wherein a bonding layer is present on the metal layer, wherein the pipe additionally has an outer layer, and wherein the bonding layer is applied as a plasma coating.

16. The method according to claim 1, wherein the motor vehicle pipe is configured for fuels and/or hydraulic fluids.

17. The method according to claim 1, wherein the bonding layer is applied with a layer thickness of 10 to 700 nm.

18. The method according to claim 10, wherein the at least one polymer is at least one polyamide and/or at least one polyolefin.

19. The method according to claim 12, wherein the chrome-free intermediate layer consists of or essentially consists of at least one phosphatizing agent.
